(19) United States
(12) Patent Application Publication
(10) Pub. No.: US 2020/0163202 A1
(43) Pub. Date: May 21, 2020

(54) NOISE SUPPRESSION CIRCUIT DEVICE

(71) Applicants: Inventec (Pudong) Technology Corp., Shanghai (CN); Inventec Corporation, Taipei (TW)

(72) Inventors: Yen-Hao Chen, Taipei (TW); Lin-Zong Zheng, Taipei (TW); Ding-Bing Lin, Taipei (TW); Min-Hung Hsieh, Taipei (TW)

(21) Appl. No.: 16/223,010

(22) Filed: Dec. 17, 2018

(30) Foreign Application Priority Data
Nov. 21, 2018 (CN) 201811387995.6

(51) Int. Cl. H04B 3/28; H05K 1/02

(52) U.S. Cl. CPC H05K 1/0236; H05K 1/0231; H05K 2201/09281; H05K 2201/093; H05K 1/0233

(57) ABSTRACT

A noise suppression circuit device includes a baseboard, a decoupling capacitor set, a power bus structure, a band-stop filter unit and an electromagnetic band-gap structure. The decoupling capacitor set is disposed on the baseboard for isolating noise of a first frequency band. The power bus structure is disposed on the baseboard for isolating noise of a second frequency band. The band-stop filter unit is disposed on the baseboard for isolating at least a portion of noise of a third frequency band. The electromagnetic band-gap structure is disposed on the baseboard for isolating noise of a fourth frequency band.

### BACKGROUND OF THE INVENTION

### 1. Field of the Invention

The invention relates to a noise suppression circuit device, and more particularly, a noise suppression circuit device integrating a plurality of noise isolation means.

### 2. Description of the Prior Art

When a circuit is formed on a circuit board, the correctness of a signal transmitted through a wire is often affected by noise. Especially in the applications of high speed signal transmission, noise suppression has been a difficult problem to be resolved.

In order to suppress noise, a convention solution is to dispose a capacitor on a circuit board to filter out noise. However, for highly complicated applications, noise is usually distributed on a plurality of frequency bands. It will fail to suppress noise spread on a plurality of frequency bands by merely disposing capacitors. Furthermore, the limitation of the circuit size has to be considered as well. Hence, a better solution is still required in the field for suppressing noise.

### SUMMARY OF THE INVENTION

An embodiment provides a noise suppression circuit device including a baseboard, a decoupling capacitor set, a power bus structure, a band-stop filter unit and an electromagnetic band-gap structure. The decoupling capacitor set is disposed on the baseboard for isolating noise of a first frequency band. The power bus structure is disposed on the baseboard for isolating noise of a second frequency band. The band-stop filter unit is disposed on the baseboard for isolating at least a portion of noise of a third frequency band. The electromagnetic band-gap structure is disposed on the baseboard for isolating noise of a fourth frequency band.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a noise suppression circuit device according to an embodiment.

FIG. 2 illustrates waveforms of insertion loss with respect to frequency according to an embodiment.

### DETAILED DESCRIPTION

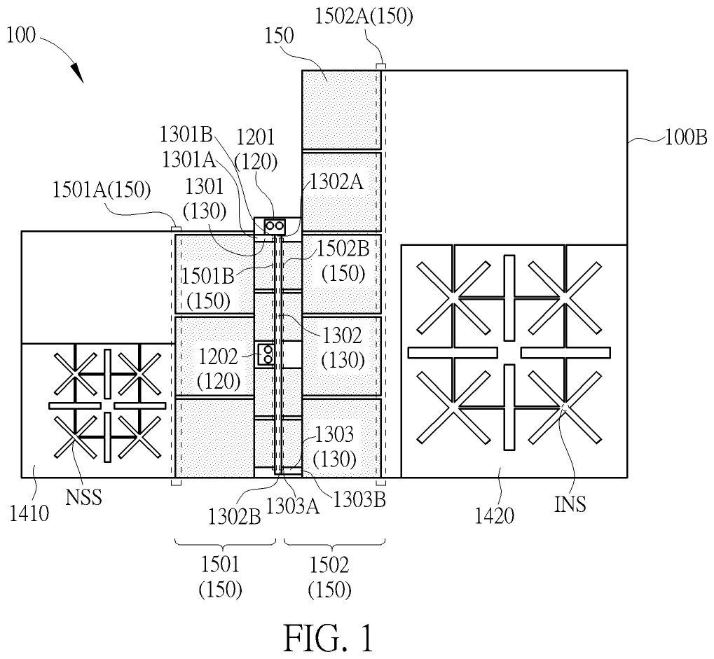

FIG. 1 illustrates a noise suppression circuit device 100 according to an embodiment. The noise suppression circuit device 100 may include a baseboard 100B, a decoupling capacitor set 120, a power bus structure 130, a first band-stop filter unit 1410 and an electromagnetic band-gap (EBG) structure 150. For example, the baseboard 100B may be (but not limited to) a printed circuit board.

The decoupling capacitor set 120 may be disposed on the baseboard 100B for isolating noise of a first frequency band. The power bus structure 130 may be disposed on the baseboard 100B for isolating noise of a second frequency band. The first band-stop filter unit 1410 may be disposed on the baseboard 100B for isolating at least a first portion of noise of a third frequency band. The electromagnetic band-gap structure 150 may be disposed on the baseboard 100B for isolating noise of a fourth frequency band. The said noise may include (but not limited to) noise generated between a ground layer and a power-supply layer of the baseboard 100B.

According to an embodiment, the noise suppression circuit device 100 may further include a second band-stop filter unit 1420. The second band-stop filter unit 1420 may be disposed on the baseboard 100B for isolating a second portion of noise of the third frequency band. According to an embodiment, the first band-stop filter unit 1410 and the second band-stop filter unit 1420 may each be a quarter-wavelength (¼ λ) band-stop filter unit.

According to an embodiment, the first frequency band may be lower than the second frequency band, the second frequency band may be lower than the fourth frequency band, and the fourth frequency band may be lower than the third frequency band. For example, the first frequency band may be a low frequency band such as a frequency band lower than 1 Gigahertz (GHz). The second frequency band may be between 1 GHz to 2 GHz. The third frequency band may be of 11 GHz. The fourth frequency band may be between 5.7 GHz to 6 GHz. According to an embodiment, regarding the isolation of noise, for the 22 GHz frequency band of the first portion of noise of the third frequency band, the noise isolation may be greater than 30 dB. For the 11 GHz frequency band of the second portion of noise of the third frequency band, the noise isolation may be greater than 50 dB. For the second frequency band, the noise isolation may be about 50 dB. The abovementioned noise isolations may merely be examples.

The abovementioned frequencies are merely examples instead of limiting the scope of embodiments. As described, by means of the decoupling capacitor set 120, the power bus structure 130, the first band-stop filter unit 1410, the second band-stop filter unit 1420 and the electromagnetic band-gap structure 150, the noise suppression circuit device 100 may be used to suppress noise of multiple frequency bands from a low frequency to a high frequency.

As shown in FIG. 1, the power bus structure 130 may have a Z-shape. The power bus structure 130 may include an upper horizontal portion 1301, a vertical portion 1302 and a lower horizontal portion 1303. The upper horizontal portion 1301 may include a first upper-horizontal terminal 1301A and a second upper-horizontal terminal 1301B. The vertical portion 1302 may include a first vertical terminal 1302A and a second vertical terminal 1302B wherein the first vertical terminal 1302A may be coupled to the second upper-horizontal terminal 1301B. The lower horizontal portion 1303 may include a first lower-horizontal terminal 1303A and a second lower-horizontal terminal 1303B where the first lower-horizontal terminal 1303A may be coupled to the second vertical terminal 1302B.

The upper horizontal portion 1301, the vertical portion 1302 and the lower horizontal portion 1303 may substantially form the Z-shape.

According to an embodiment, the decoupling capacitor set 120 may include a first capacitor 1201. The upper horizontal portion 1301 of the power bus structure 130 may be coupled to the first capacitor 1201. According to an embodiment, the decoupling capacitor set 120 may further include a second capacitor 1202, and the vertical portion 1302 of the power bus structure 130 may be coupled to the second capacitor 1202. For example, the first capacitor 1201 may have a capacitance of 2.2 nanofarads (nF). The second capacitor 1202 may have a capacitance of 1.8 nanofarads (nF). The abovementioned capacitances may be merely examples instead of limiting the scope of the embodiments.

According to an embodiment, the electromagnetic band-gap structure 150 may include a first electromagnetic band-gap structure portion 1501 and a second electromagnetic band-gap structure portion 1502. The first electromagnetic band-gap structure portion 1501 and the second electromagnetic band-gap structure portion 1502 may be substantially disposed in parallel with the vertical portion 1302 of the power bus structure 130. The vertical portion 1302 of the power bus structure 130 may be disposed between the first electromagnetic band-gap structure portion 1501 and the second electromagnetic band-gap structure portion 1502.

As shown in FIG. 1, the first electromagnetic band-gap structure portion 1501 may include a first outer side 1501A and a first inner side 1501B. The second electromagnetic band-gap structure portion 1502 may include a second outer side 1502A and a second inner side 1502B. The first band-stop filter unit 1410 may be disposed at the first outer side 1501A of the first electromagnetic band-gap structure portion 1501. The vertical portion 1302 of the power bus structure 130 may be disposed between the first inner side 1501B of the first electromagnetic band-gap structure portion 1501 and the second inner side 1502B of the second electromagnetic band-gap structure portion 1502. The second band-stop filter unit 1420 may be disposed at the second outer side 1502A of the second electromagnetic band-gap structure portion 1502.

According to an embodiment, the first band-stop filter unit 1410 may cover a noise source NSS. The second band-stop filter unit 1420 may cover an isolated node INS. The noise of the abovementioned first frequency band, the second frequency band, the third frequency band and the fourth frequency band may be from the noise source NSS. The noise suppression circuit device 100 may be used to reduce an effect caused by the noise from the noise source NSS upon the isolated node INS. In addition, the noise suppression circuit device 100 may suppress noise from other sources. By means of the layout shown in FIG. 1, the decoupling capacitor set 120, the power bus structure 130, the first band-stop filter unit 1410, the second band-stop filter unit 1420 and the electromagnetic band-gap structure 150 may be properly integrated. Hence, noise of more frequency bands may be suppressed without increasing circuit size. For example, by means of the noise suppression circuit device 100 shown in FIG. 1, the frequency band of noise suppression may be from a very low frequency to more than 40 GHz with a condition of isolating noise by 30 dB.

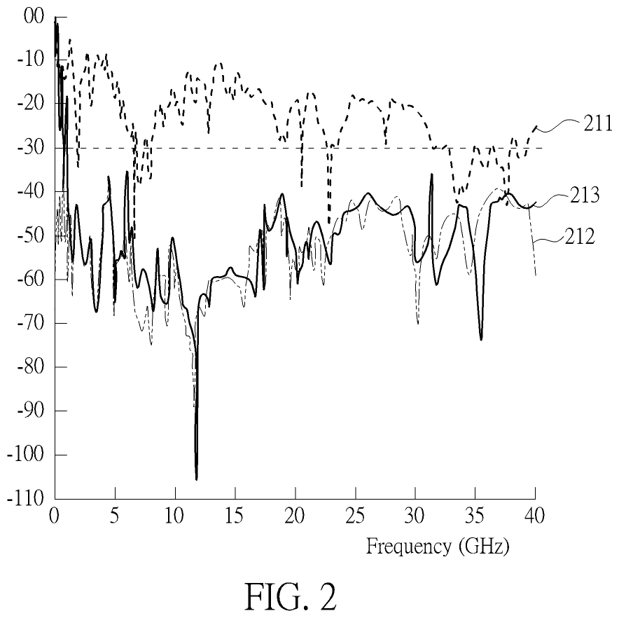

FIG. 2 illustrates waveforms of insertion loss with respect to frequency according to an embodiment. In FIG. 2, the vertical axis may correspond to insertion loss values, and the horizontal axis may correspond to frequencies. A first curve 211 may correspond to results measured without using the noise suppression circuit device 100 provided by an embodiment. As shown by the first curve 211, the insertion loss may be higher, and this means the effect caused by noise may be greater. A second curve 212 may correspond to results measured when applying the power bus structure 130, the first band-stop filter unit 1410, the second band-stop filter unit 1420 and the electromagnetic band-gap structure 150. According to the second curve 212, the insertion loss may be lower, and this means the effect caused by noise is smaller. A third curve 213 may correspond to results measured when applying the decoupling capacitor set 120, the power bus structure 130, the first band-stop filter unit 1410, the second band-stop filter unit 1420 and the electromagnetic band-gap structure 150. According to the third curve 213, the insertion loss may be further lowered, and this means the effect caused by noise is further reduced.

In summary, by means of the noise suppression circuit device 100 provided by an embodiment, a plurality of noise suppression means can be effectively integrated, and the isolation of noise can be improved. Moreover, by means of a complete and verified solution of integrated circuit layout, the trade-off problems on a circuit can be avoided, thereby saving circuit layout area on the baseboard 100B. Hence, the present invention provides an efficient solution to suppress noise.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A noise suppression circuit device comprising:
a baseboard;
a decoupling capacitor set disposed on the baseboard and configured to isolate noise of a first frequency band;
a power bus structure disposed on the baseboard and configured to isolate noise of a second frequency band;
a first band-stop filter unit disposed on the baseboard and configured to isolate at least a first portion of noise of a third frequency band; and
an electromagnetic band-gap structure disposed on the baseboard and configured to isolate noise of a fourth frequency band.

2. The noise suppression circuit device of claim 1 further comprising:
a second band-stop filter unit disposed on the baseboard and configured to isolate a second portion of noise of the third frequency band.

3. The noise suppression circuit device of claim 2 wherein the first band-stop filter unit and the second band-stop filter unit are quarter-wavelength band-stop filter units.

4. The noise suppression circuit device of claim 1 wherein the first frequency band is lower than the second frequency band, the second frequency band is lower than the fourth frequency band, and the fourth frequency band is lower than the third frequency band.

5. The noise suppression circuit device of claim 1, wherein:
the power bus structure has a Z-shape;
the power bus structure comprises an upper horizontal portion, a vertical portion and a lower horizontal portion;
the upper horizontal portion comprises a first upper-horizontal terminal and a second upper-horizontal terminal;
the vertical portion comprises a first vertical terminal and a second vertical terminal wherein the first vertical terminal is coupled to the second upper-horizontal terminal;
the lower horizontal portion comprises a first lower-horizontal terminal and a second lower-horizontal terminal wherein the first lower-horizontal terminal is coupled to the second vertical terminal; and
the upper horizontal portion, the vertical portion and the lower horizontal portion substantially form the Z-shape.

6. The noise suppression circuit device of claim 5, wherein the decoupling capacitor set comprises a first capacitor, and the upper horizontal portion of the power bus structure is coupled to the first capacitor.

7. The noise suppression circuit device of claim 6, wherein the decoupling capacitor set further comprises a second capacitor, and the vertical portion of the power bus structure is coupled to the second capacitor.

8. The noise suppression circuit device of claim 5, wherein:
the electromagnetic band-gap structure comprises a first electromagnetic band-gap structure portion and a second electromagnetic band-gap structure portion;
the first electromagnetic band-gap structure portion and the second electromagnetic band-gap structure portion are substantially disposed in parallel with the vertical portion of the power bus structure; and
the vertical portion of the power bus structure is disposed between the first electromagnetic band-gap structure portion and the second electromagnetic band-gap structure portion.

9. The noise suppression circuit device of claim 8, further comprising a second band-stop filter unit disposed on the baseboard and configured to isolate a second portion of noise of the third frequency band, wherein:
the first electromagnetic band-gap structure portion comprises a first outer side and a first inner side;
the second electromagnetic band-gap structure portion comprises a second outer side and a second inner side;
the first band-stop filter unit is disposed at the first outer side of the first electromagnetic band-gap structure portion;
the vertical portion of the power bus structure is disposed between the first inner side of the first electromagnetic band-gap structure portion and the second inner side of the second electromagnetic band-gap structure portion; and
the second band-stop filter unit is disposed at the second outer side of the second electromagnetic band-gap structure portion.

10. The noise suppression circuit device of claim 9, wherein:
the first band-stop filter unit covers a noise source;
the second band-stop filter unit covers an isolated node;
the noise of the first frequency band, the second frequency band, the third frequency band and the fourth frequency band is from the noise source; and
the noise suppression circuit device is configured to reduce an effect caused by the noise from the noise source upon the isolated node.
